(19) United States
(12) Patent Application Publication
(10) Pub. No.: US 2025/0300081 A1
(43) Pub. Date: Sep. 25, 2025

(54) SEMICONDUCTOR DEVICE

(71) Applicant: Samsung Electronics Co., Ltd., Suwon-si (KR)

(72) Inventors: Yunsuk Nam, Suwon-si (KR); Jinkyu Kim, Suwon-si (KR); Yoonbeom Park, Suwon-si (KR); Yongwoo Lee, Suwon-si (KR); Soohang Chae, Suwon-si (KR); Keun Hwi Cho, Suwon-si (KR); Hagju Cho, Suwon-si (KR)

(21) Appl. No.: 18/916,805

(22) Filed: Oct. 16, 2024

(30) Foreign Application Priority Data
Mar. 20, 2024 (KR) 10-2024-0038287

(51) Int. Cl. H01L 23/528; H01L 23/522; H01L 29/417

(52) U.S. Cl. CPC H01L 23/5286; H01L 23/5226; H10D 30/6729

(57) ABSTRACT

A semiconductor device includes a substrate and a first block thereon. The first block includes a first source/drain pattern, a second source/drain pattern, and a third source/drain pattern between the first and second source/drain patterns, spaced apart in a first direction parallel to the substrate's upper surface. A first lower power line is on a lower portion of the substrate, and a second lower power line is spaced apart from the first lower power line in the first direction, both extending in the first direction. A first rear surface via in the substrate, connecting the first lower power line and the first source/drain pattern. A second rear surface via in the substrate, connecting the second lower power line and the second source/drain pattern. A third rear surface via in the substrate, connected to the third source/drain pattern, and extends in a second direction perpendicular to the first direction.

### CROSS-REFERENCE TO RELATED APPLICATIONS

This U.S. non-provisional patent application claims priority under 35 U.S.C. § 119 to Korean Patent Application No. 10-2024-0038287, filed on Mar. 20, 2024, the entire contents of which are hereby incorporated by reference.

### BACKGROUND OF THE INVENTION

The present disclosure herein relates to a semiconductor device, and more particularly, to a semiconductor device including a field effect transistor.

A semiconductor device includes an integrated circuit composed of metal-oxide-semiconductor field effect transistors (MOSFET). As a size and a design rule of the semiconductor device are gradually reduced, scaling down the metal-oxide-semiconductor field effect transistors is gradually being accelerated. When the metal-oxide-semiconductor field effect transistors are scaled down, operation characteristics of the semiconductor device may be deteriorated. Accordingly, various methods for overcoming limitations caused by high integration of the semiconductor device, and forming the semiconductor device to have improved performance, are being studied.

### SUMMARY OF THE INVENTION

The present disclosure provides a semiconductor device with improved electrical characteristics and reliability.

An embodiment of the inventive concept provides a semiconductor device including a substrate, and a first block on the substrate, wherein the first block includes a first source/drain pattern, a second source/drain pattern, and a third source/drain pattern between the first source/drain pattern and the second source/drain pattern, which are spaced apart from each other in a first direction parallel to an upper surface of the substrate, a first lower power line on a lower portion of the substrate, and a second lower power line spaced apart from the first lower power line in the first direction, which extend in the first direction, a first rear surface via in the substrate, and connecting the first lower power line and the first source/drain pattern, a second rear surface via in the substrate, and connecting the second lower power line and the second source/drain pattern, and a third rear surface via in the substrate, and connected to the third source/drain pattern, and the third rear surface via extends in a second direction parallel to the upper surface of the substrate, and perpendicular to the first direction.

In an embodiment of the inventive concept, a semiconductor device includes a channel pattern including a plurality of semiconductor patterns stacked spaced apart from each other, a first source/drain pattern and a second source/drain pattern respectively connected to opposite sides of the channel pattern, and spaced apart from each other in a first direction, a gate electrode, on the channel pattern, including a plurality of inner electrodes respectively between the plurality of semiconductor patterns, a first rear surface via connected to the first source/drain pattern, a second rear surface via connected to the second source/drain pattern, a lower power line under and connected to at least one of the first rear surface via or the second rear surface via, an interlayer insulating layer on the first source/drain pattern and the second source/drain pattern, and being in contact with upper surfaces of the first and second source/drain patterns, and a first insulating pattern between the first rear surface via and the second rear surface via.

In an embodiment of the inventive concept, a semiconductor device includes an insulating substrate, and a first block and a second block on the insulating substrate, wherein the first block includes a first source/drain pattern, a second source/drain pattern, and a third source/drain pattern between the first source/drain pattern and the second source/drain pattern, which are spaced apart from each other in a first direction parallel to an upper surface of the insulating substrate, a first lower power line on a lower portion of the insulating substrate, and a second lower power line spaced apart from the first lower power line in the first direction, which extend in the first direction, a first rear surface via in the insulating substrate, and connecting the first lower power line and the first source/drain pattern, a second rear surface via in the insulating substrate, and connecting the second lower power line and the second source/drain pattern, and a third rear surface via in the insulating substrate, and connected to the third source/drain pattern, the second block includes a channel pattern including a plurality of semiconductor patterns stacked spaced apart from each other, and a fourth source/drain pattern and a fifth source/drain pattern respectively connected to opposite sides of the channel pattern, and spaced apart from each other in the first direction, and the third rear surface via extends in a second direction parallel to an upper surface of the insulating substrate, and perpendicular to the first direction to connect to any one of the fourth source/drain pattern or the fifth source/drain pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view for describing a semiconductor device according to embodiments of the inventive concept;

FIGS. 2A, 2B, 2C, 2D, and 2E are respective cross-sectional views taken along lines A-A′, B-B′, C-C′, D-D′, and E-E′ of FIG. 1;

FIG. 3A is a perspective view schematically illustrating transistors disposed in region R1 of FIG. 1;

FIG. 3B is an enlarged view of block A1 of FIG. 2A;

FIG. 4 is a perspective view schematically illustrating transistors disposed in region R2 of FIG. 1;

FIG. 5 is a perspective view schematically illustrating transistors disposed in region R3 of FIG. 1;

FIG. 6 is a perspective view schematically illustrating connection of transistors disposed in regions R1, R2, and R3 of FIG. 1;

FIG. 7 is a perspective view schematically illustrating transistors disposed in region R4 of FIG. 1;

FIG. 8 is a perspective view schematically illustrating transistors disposed in region R5 of FIG. 1; and

FIGS. 9A to 9H are cross-sectional views for describing a method for manufacturing a semiconductor device according to embodiments of the inventive concept.

### DETAILED DESCRIPTION

Hereinafter, a semiconductor device according to the inventive concept will be described with reference to the drawings.

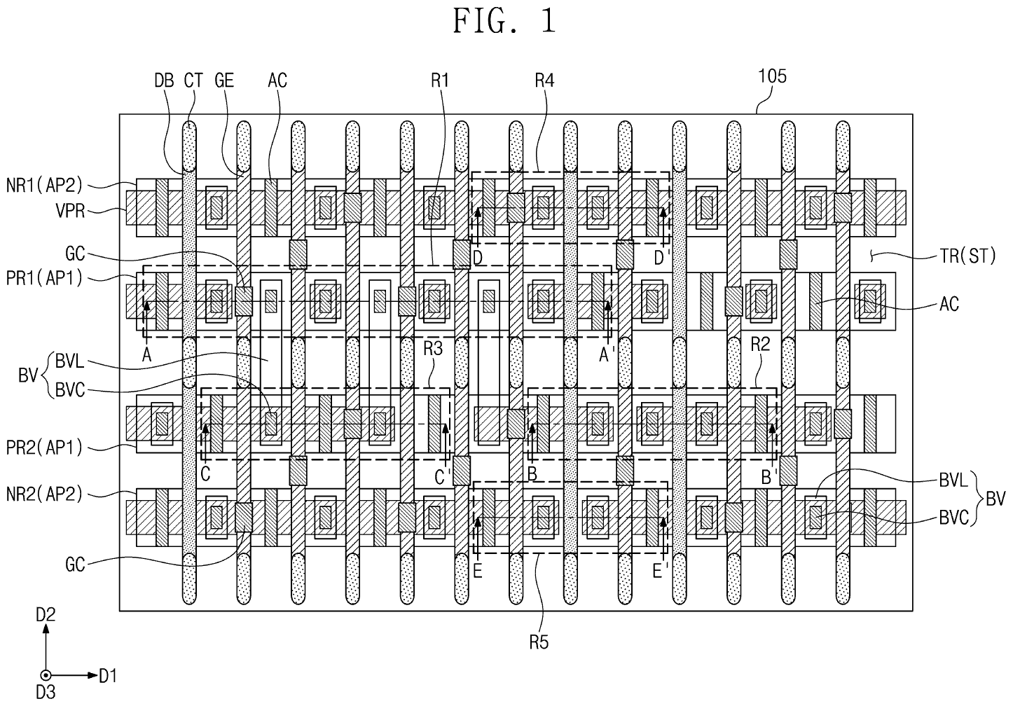

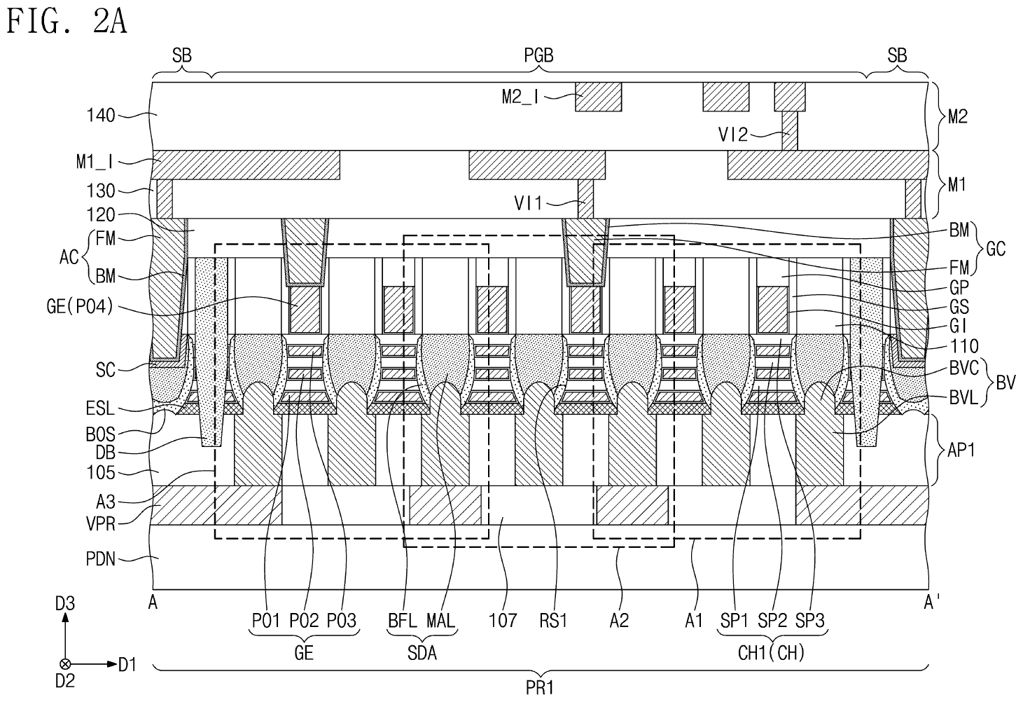

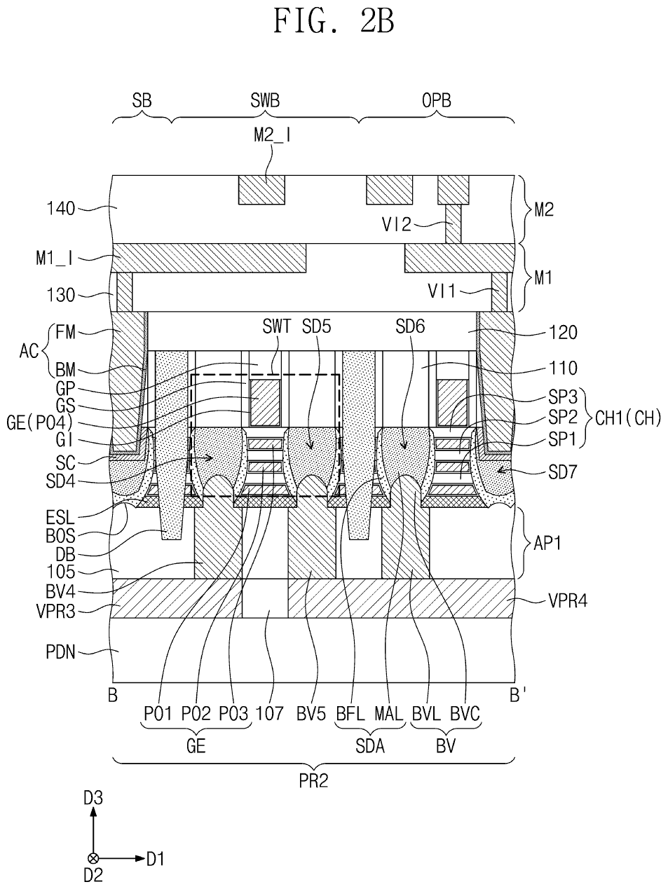

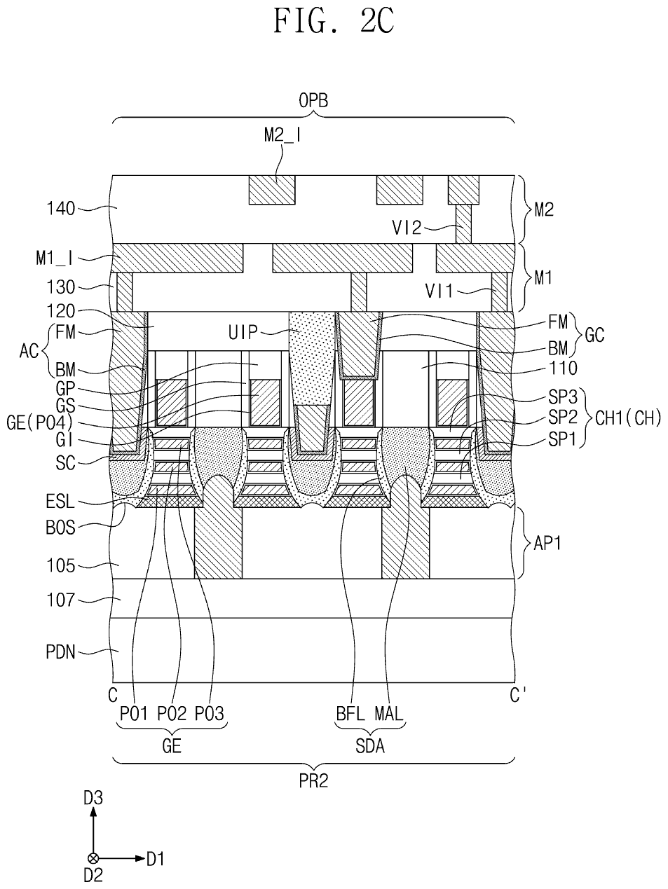

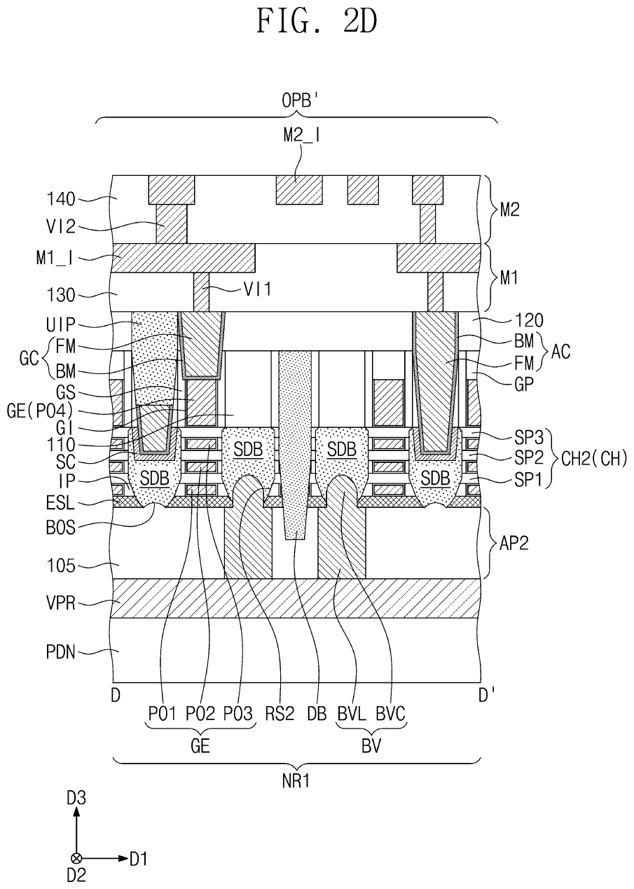

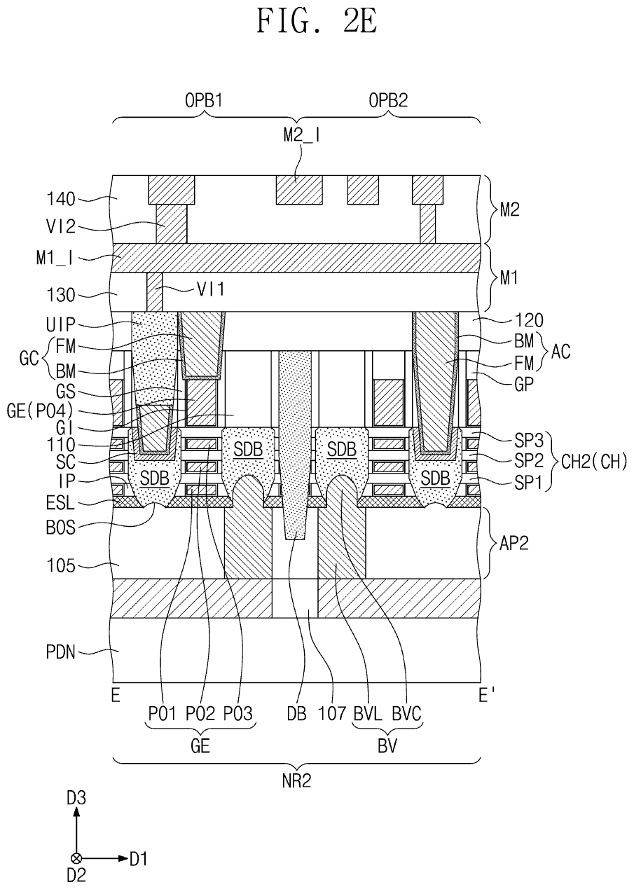

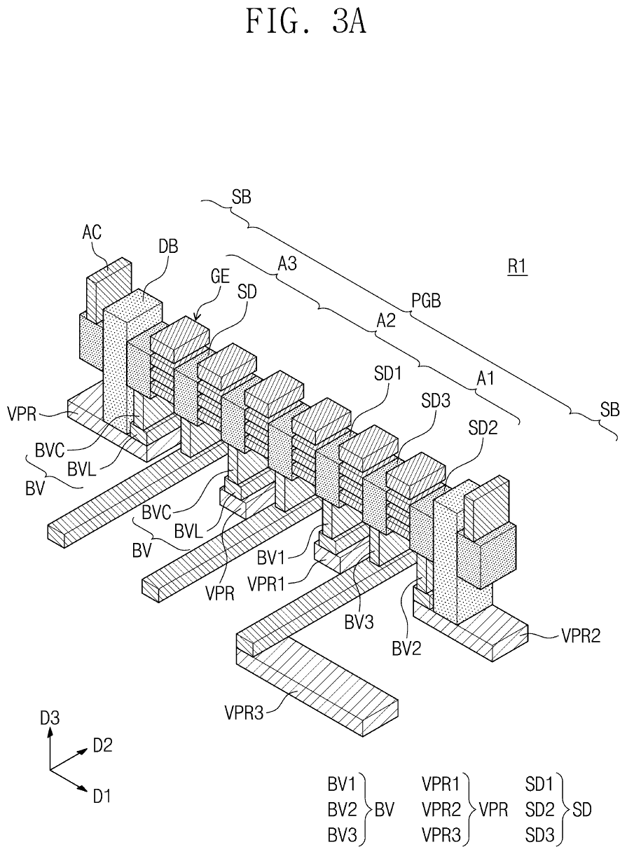

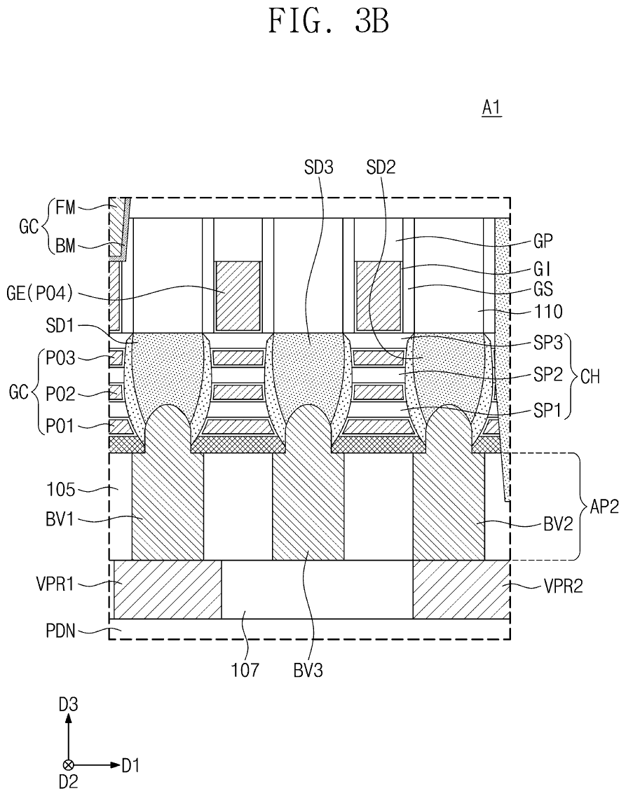

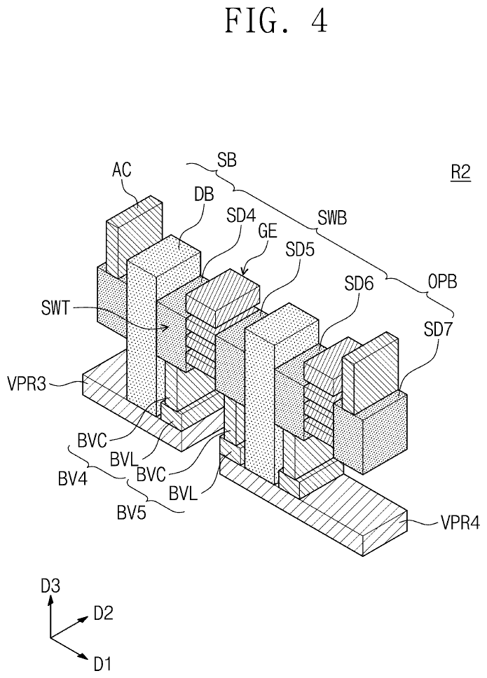

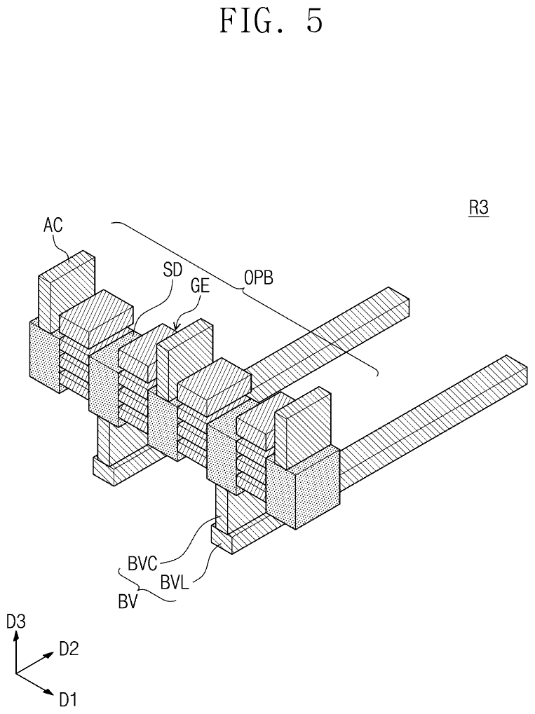

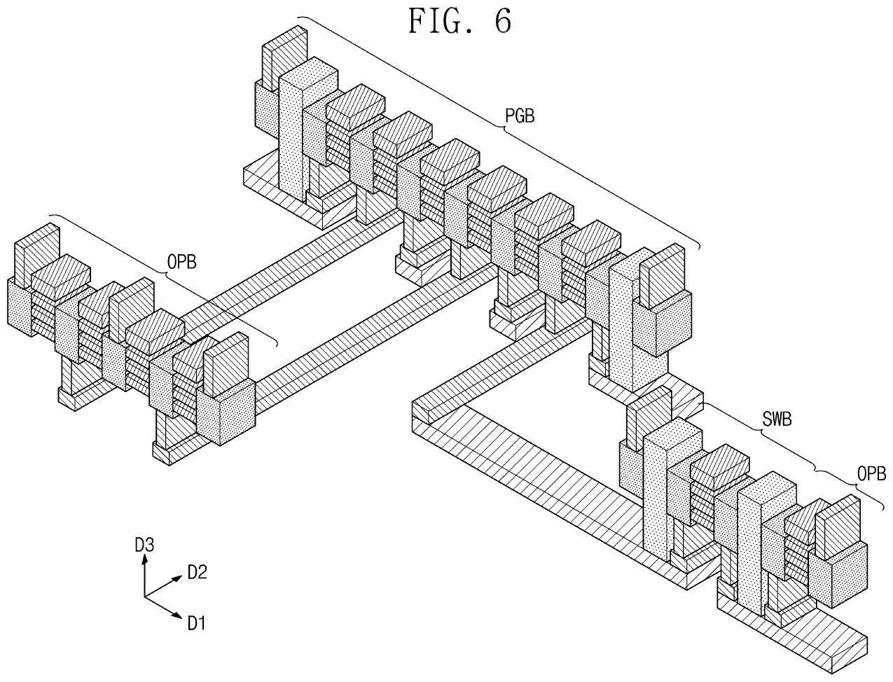

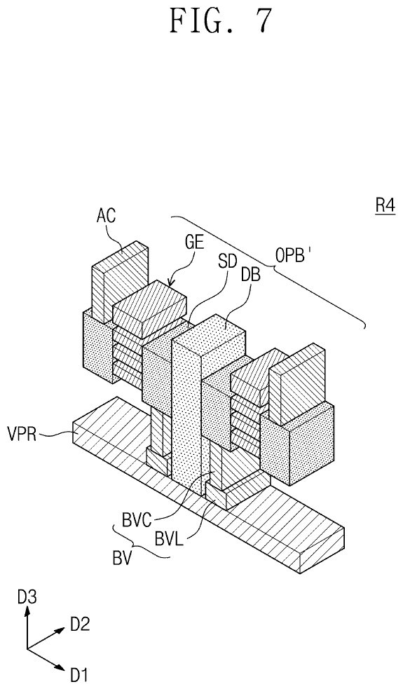

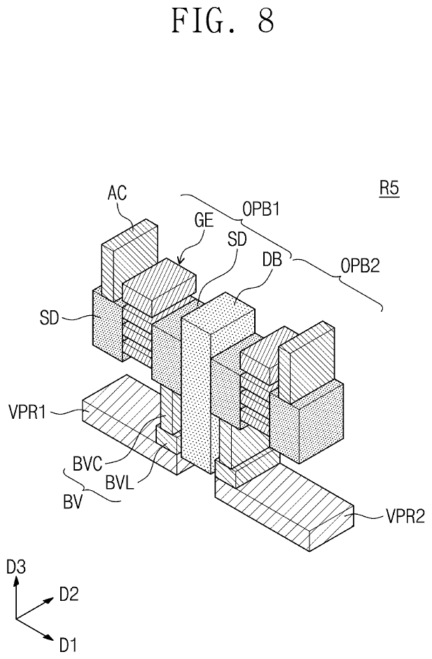

FIG. 1 is a plan view for describing the semiconductor device according to embodiments of the inventive concept. FIGS. 2A, 2B, 2C, 2D, and 2E are respective cross-sectional views taken along lines A-A′, B-B′, C-C′, D-D′, and E-E′ of FIG. 1. FIG. 3A is a perspective view schematically illustrating transistors disposed in region R1 of FIG. 1. FIG. 3B is an enlarged view of block A1 of FIG. 2A. FIG. 4 is a perspective view schematically illustrating transistors disposed in region R2 of FIG. 1. FIG. 5 is a perspective view schematically illustrating transistors disposed in region R3 of FIG. 1. FIG. 6 is a perspective view schematically illustrating connection of transistors disposed in regions R1, R2, and R3 of FIG. 1. FIG. 7 is a perspective view schematically illustrating transistors disposed in region R4 of FIG. 1. FIG. 8 is a perspective view schematically illustrating transistors disposed in region R5 of FIG. 1.

Referring to FIG. 1, a plurality of blocks disposed on a substrate 105 may be provided. Each of the blocks includes at least one transistor. The term “block,” as used herein, refers to a unit of a set in which the corresponding transistor performs a specific function. For example, as described later, the blocks may include a power gating block PGB, a switching block SWB, an operation block OPB, and the like (see FIG. 6). The power gating block PGB may control a power supply of a specific block inside the semiconductor device. In addition, the power gating block PGB may be connected to the switching block SWB to supply or block power to the specific block as needed. The switching block SWB may include a switching transistor. The switching transistor may control flow of current to switch ‘on’ and ‘off’ states of an electrical signal. For example, when a voltage of at least a threshold voltage is applied to a control terminal (for example, a gate), the switching transistor may have the ‘on’ state. The operation block may include logic cells in which transistors constituting a logic circuit for performing a specific function are disposed. The logic cell may mean a logic element (for example, AND, OR, XOR, XNOR, an inverter, or the like) that performs the specific function.

For example, the substrate 105 may include a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a first direction D1.

The substrate 105 may include a first region R1, a second region R2, a third region R3, a fourth region R4, and a fifth region R5. Each of the first to fifth regions R1 to R5 may be placed in any one among the first PMOSFET region PR1, the second PMOSFET region PR2, the first NMOSFET region NR1, and the second NMOSFET region NR2. For example, the first region R1 may be placed in the first PMOSFET region PR1, the second region R2 may be placed in the second PMOSFET region PR2, the third region R3 may be placed in the second PMOSFET region PR2, the fourth region R4 may be placed in the first NMOSFET region NR1, and the fifth region R5 may be placed in the second NMOSFET region NR2. The placement relationship above is an example, and the first to fifth regions R1 to R5 may be variously placed in the first PMOSFET region PR1, the second PMOSFET region PR2, the first NMOSFET region NR1, and the second NMOSFET region NR2.

In the present specification, the constitution of transistors disposed on the first PMOSFET region PR1 may be structurally the same as or similar to the constitution of transistors disposed on the second PMOSFET region PR2. In addition, the constitution of transistors disposed on the first NMOSFET region NR1 may be structurally the same as or similar to the constitution of transistors disposed on the second NMOSFET region NR2.

For convenience of description, a common portion in describing PMOSFETs on the first PMOSFET region PR1 and the second PMOSFET region PR2 will be described with reference to FIG. 2A, and a common portion in describing NMOSFETs on the first NMOSFET region NR1 and the second NMOSFET region NR2 will be described with reference to FIG. 2D.

Referring to FIGS. 1, 2A, and 2D, a first insulating pattern AP1 and a second insulating pattern AP2 may be defined by a trench TR formed on the substrate 105. The first insulating pattern AP1 may be provided on each of the first and second PMOSFET regions PR1 and PR2. The second insulating pattern AP2 may be provided on each of the first and second NMOSFET regions NR1 and NR2. The first and second insulating patterns AP1 and AP2 may extend in the first direction D1. The first and second insulating patterns AP1 and AP2 may be vertically protruding portions as a portion of the substrate 105. An element isolation film ST may be in (e.g., may fill) the trench TR. The element isolation film ST may be on (e.g., may cover) a sidewall of each of the first and second insulating patterns AP1 and AP2. For example, the element isolation film ST may include a silicon oxide film. The first and second insulating patterns AP1 and AP2 (and thus the substrate 105, which may comprise the first and second insulating patterns AP1 and AP2) may include at least any one of silicon nitride, silicon oxide, or silicon carbide.

An etch stopping layer ESL may be provided on each of the first and second insulating patterns AP1 and AP2. For example, the etch stopping layer ESL may include silicon doped with oxygen (O), carbon (C), or a combination thereof. The etch stopping layer ESL may have a single crystal. A concentration of impurities (oxygen, carbon, or a combination thereof) in the etch stopping layer ESL may be about 0.5 at % to about 2 at %. According to some embodiments, the etch stopping layer ESL may be omitted.

Each of a first channel pattern CH1 and a second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (that is, a third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon. Each of the first to third semiconductor patterns SP1, SP2, and SP3 may be a nano sheet.

As shown in FIG. 2A, a plurality of first conductive source/drain patterns SDA may be provided on the first insulating pattern AP1. A plurality of first recesses RS1 may be formed on the first insulating pattern AP1. The first conductive source/drain patterns SDA may be respectively provided in the first recesses RS1. The first conductive source/drain patterns SDA may be first conductive (for example, a p-type) impurity regions. The first channel pattern CH1 may be interposed between a pair of the first conductive source/drain patterns SDA. In other words, the stacked first to third semiconductor patterns SP1, SP2, and SP3 may connect (e.g., electrically connect) the pair of the first conductive source/drain patterns SDA.

As shown in FIG. 2D, a plurality of second conductive source/drain patterns SDB may be provided on the second insulating pattern AP2. A plurality of second recesses RS2 may be formed on the second insulating pattern AP2. The second conductive source/drain patterns SDB may be respectively provided in the second recesses RS2. The second conductive source/drain patterns SDB may be second conductive (for example, an n-type) impurity regions. The second channel pattern CH2 may be interposed between a pair of the second conductive source/drain patterns SDB. In other words, the stacked first to third semiconductor patterns SP1, SP2, and SP3 may connect (e.g., electrically connect) the pair of the second conductive source/drain patterns SDB.

As shown in FIG. 2A, each of the first conductive source/drain patterns SDA may include a buffer layer BFL and a main layer MAL on the buffer layer BFL. The buffer layer BFL may cover an inner sidewall of the first recesses RS1. The main layer MAL may fill a remaining region of the first recesses RS1, except for the buffer layer BFL. A volume of the main layer MAL may be greater than a volume of the buffer layer BFL. The buffer layer BFL and the main layer MAL may each include silicon-germanium (SiGe). Specifically, the buffer layer BFL may include germanium (Ge) at a relatively low concentration. According to another embodiment of the inventive concept, the buffer layer BFL may include only silicon (Si), except for germanium (Ge). The buffer layer BFL may have germanium (Ge) at a concentration of 0 to about 30 at %. The main layer MAL may include germanium (Ge) at a relatively high concentration. For example, the main layer MAL may have germanium (Ge) at a concentration of about 30 at % to about 70 at %. The concentration of germanium (Ge) of the main layer MAL may increase in the third direction D3. For example, a lower portion of the main layer MAL adjacent to the buffer layer BFL may have a germanium (Ge) concentration of about 40 at %, but an upper portion of the main layer MAL may have a germanium (Ge) concentration of about 60 at %. Each of the buffer layer BFL and the main layer MAL may include impurities (for example, boron, gallium, or indium) such that the first conductive source/drain patterns SDA are a p-type. An impurity concentration of the main layer MAL may be greater than an impurity concentration of the buffer layer BFL. The buffer layer BFL may protect the main layer MAL during a process, to be described later, of replacing sacrificial layers with first to third inner electrodes PO1, PO2, and PO3 of a gate electrode GE. In other words, the buffer layer BFL may prevent an etching material that removes the sacrificial layers from infiltrating into and etching the main layer MAL.

Referring to FIG. 2D, each of the second conductive source/drain patterns SDB may include silicon (Si). The second conductive source/drain patterns SDB may further include impurities (for example, phosphor, arsenic, or antimony) such that the second conductive source/drain patterns SDB are an n-type.

According to an embodiment of the inventive concept, as shown in FIGS. 2A and 2D, the first and second conductive source/drain patterns SDA and SDB may each include a concave bottom BOS. The concave bottom BOS may be concave in the third direction D3. According to some embodiments, the first and second conductive source/drain patterns SDA and SDB may not each have the concave bottom BOS. For example, some of the first and second conductive source/drain patterns SDA and SDB may have convex bottom surfaces.

As shown in FIGS. 1, 2A, and 2D, gate electrodes GE extending across the first and second channel patterns CH1 and CH2 in a second direction D2 may be provided. The gate electrodes GE may vertically overlap the first and second channel patterns CH1 and CH2. The gate electrode GE may include a first inner electrode PO1 interposed between the etch stopping layer ESL and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3. According to the present embodiment, the etch stopping layer ESL may be interposed between the first inner electrode PO1 and the substrate 105. A gate insulating film GI may be interposed between the first inner electrode PO1 and the etch stopping layer ESL. The transistor according to the present embodiment may be a three-dimensional field effect transistor (for example, MBCFET or GAAFET) in which the gate electrode GE three-dimensionally surrounds a channel.

As shown in FIG. 1, gate cutting patterns CT may be disposed on a border of a cell. The gate cutting patterns CT may separate adjacent gate electrodes GE. The gate cutting patterns CT may separate adjacent isolation structures DB. The gate cutting patterns CT may include an insulating material such as a silicon oxide film, a silicon nitride film, or a combination thereof.

As shown in FIGS. 2A and 2D, a pair of gate spacers GS may be respectively disposed on opposite (e.g., both) sidewalls of the outer electrode PO4 of the gate electrode GE. The gate spacers GS may extend along the gate electrode GE in the second direction D2. Upper surfaces of the gate spacers GS may be higher than an upper surface of the gate electrode GE. The upper surfaces of the gate spacers GS may be coplanar with an upper surface of a first interlayer insulating film 110 to be described later. The gate spacers GS may include at least one of SiCN, SiCON, or SiN. As another example, the gate spacers GS may include a multi-layer composed of at least two of SiCN, SiCON, or SiN.

A gate capping pattern GP may be provided on the gate electrode GE. The gate capping pattern GP may extend along the gate electrode GE in the second direction D2. The gate capping pattern GP may include a material having etching selectivity with respect to first and second interlayer insulating films 110 and 120 to be described later. Specifically, the gate capping pattern GP may include at least one of SION, SiCN, SiCON, or SiN.

The gate insulating film GI may be interposed between the gate electrode GE and the first channel pattern CH1, and between the gate electrode GE and the second channel pattern CH2. The gate insulating film GI may cover an upper surface, a bottom surface, and both sidewalls of each of the first to third semiconductor patterns SP1, SP2, and SP3. The gate insulating film GI may cover an upper surface of the element isolation film ST under the gate electrode GE. The gate insulating film GI may be interposed between the first inner electrode PO1 and the etch stopping layer ESL.

According to an embodiment of the inventive concept, the gate insulating film GI may include a silicon oxide film, a silicon oxynitride film, and/or a high dielectric constant film. The high dielectric constant film may include a material having a higher dielectric constant than the silicon oxide film. For example, the high dielectric constant material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

The gate electrode GE may include a first metal pattern, and a second metal pattern on the first metal pattern. The first metal pattern may be provided on the gate insulating film GI to be adjacent to the first to third semiconductor patterns SP1, SP2, and SP3. The first metal pattern may include a work function metal that controls a threshold voltage of the transistor. A targeted threshold voltage of the transistor may be achieved by controlling a thickness and a composition of the first metal pattern. For example, the first to third inner electrodes PO1, PO2, and PO3 of the gate electrode GE may be composed of the first metal pattern including the work function metal.

The first metal pattern may include a metal nitride film. For example, the first metal pattern may include at least one metal selected from the group consisting of titanium (Ti), tantalum (Ta), aluminum (Al), tungsten (W), molybdenum (Mo), and a combination thereof, and nitrogen (N). Furthermore, the first metal pattern may further include carbon (C). The first metal pattern may include a plurality of stacked work function metal films.

The second metal pattern may include a metal having a lower resistance than the first metal pattern. For example, the second metal pattern may include at least one metal selected from the group consisting of tungsten (W), aluminum (Al), titanium (Ti), tantalum (Ta), and a combination thereof. For example, the outer electrode PO4 of the gate electrode GE may include the first metal pattern and the second metal pattern on the first metal pattern.

As shown in FIGS. 2D and 2E, inner spacers IP may be provided on the first and second NMOSFET regions NR1 and NR2. In other words, the inner spacers IP may be provided on the second insulating pattern AP2. The inner spacers IP may be respectively interposed between the first to third inner electrodes PO1, PO2, and PO3 of the gate electrode GE and the second conductive source/drain pattern SDB. The inner spacers IP may be in direct contact with the second conductive source/drain pattern SDB. Each of the first to third inner electrodes PO1, PO2, and PO3 of the gate electrode GE may be spaced apart from the second conductive source/drain pattern SDB by the inner spacer IP.

As shown in FIGS. 2A and 2D, the first interlayer insulating film 110 may be provided on the substrate 105. The first interlayer insulating film 110 may cover the gate spacers GS and the first and second conductive source/drain patterns SDA and SDB. The first interlayer insulating film 110 may be in contact with an upper surface of each of the first and second conductive source/drain patterns SDA and SDB.

An upper surface of the first interlayer insulating film 110 may be substantially coplanar with an upper surface of the gate capping pattern GP and an upper surface of the gate spacers GS. A second interlayer insulating film 120 covering the gate capping pattern GP may be disposed on the first interlayer insulating film 110. A third interlayer insulating film 130 may be provided on the second interlayer insulating film 120. A fourth interlayer insulating film 140 may be provided on the third interlayer insulating film 130. For example, the first to fourth interlayer insulating films 110 to 140 may include a silicon oxide film.

Active contacts AC in (e.g., penetrating) the first and second interlayer insulating films 110 and 120 to be respectively electrically connected to the first and second conductive source/drain patterns SDA and SDB may be provided. Each of the active contacts AC may be provided so as to be adjacent to one side of the gate electrode GE. When seen on a plane (e.g., in a plan view), the active contact AC may have a form of a bar (e.g., a rectangle) extending in the second direction D2.

The active contact AC may be a self-aligned contact. In other words, the active contact AC may be self-aligned and formed using the gate capping pattern GP and the gate spacer GS. For example, the active contact AC may at least partially cover (i.e., may cover at least a portion of) a sidewall of the gate spacer GS. Although not shown, the active contact AC may partially cover the upper surface of the gate capping pattern GP.

A metal-semiconductor compound layer SC such as a silicide layer may be each interposed between the active contact AC and the first conductive source/drain patterns SDA, and between the active contact AC and the second conductive source/drain patterns SDB. The active contact AC may be electrically connected, through the metal-semiconductor compound layer SC, to the first and second conductive source/drain patterns SDA and SDB. For example, the metal-semiconductor compound layer SC may include at least one of titanium silicide, tantalum silicide, tungsten silicide, nickel silicide, or cobalt silicide.

Gate contacts GC in (e.g., penetrating) the second interlayer insulating film 120 and the gate capping pattern GP to be respectively electrically connected to the gate electrodes GE may be provided. The gate contact GC may be freely disposed on the gate electrode GE without limitation of a position thereof.

As shown in FIG. 2D, an upper portion of the active contact AC adjacent to the gate contact GC may be filled with an upper insulating pattern UIP. A bottom surface of the upper insulating pattern UIP may be lower than a bottom surface of the gate contact GC. In other words, an upper surface of the active contact AC adjacent to the gate contact GC may be lower than the bottom surface of the gate contact GC due to the upper insulating pattern UIP. Accordingly, a limitation that the gate contact GC is in contact with the active contact AC adjacent thereto to generate a short circuit may be impeded/prevented. For example, the upper insulating pattern UIP may include a silicon-based insulating material (for example, a silicon oxide film, a silicon nitride film, or a silicon oxynitride film).

Each of the active contact AC and the gate contact GC may include a conductive pattern FM and a barrier pattern BM surrounding the conductive pattern FM. For example, the conductive pattern FM may include at least one metal among aluminum, copper, tungsten, molybdenum, or cobalt. The barrier pattern BM may cover sidewalls and a bottom surface of the conductive pattern FM. The barrier pattern BM may include a metal film/a metal nitride film. The metal film may include at least one of titanium, tantalum, tungsten, nickel, cobalt, or platinum. The metal nitride film may include at least one of a titanium nitride (TiN) film, a tantalum nitride (TaN) film, a tungsten nitride (WN) film, a nickel nitride (NiN) film, a cobalt nitride (CON) film, or a platinum nitride (PIN) film.

A first upper metal layer M1 may be provided in the third interlayer insulating film 130. The first upper metal layer M1 may include first lines M1_I. The first lines M1_I of the first upper metal layer M1 may extend parallel to each other in the first direction D1.

According to embodiments of the inventive concept, a power line for supplying a semiconductor device with power may be in (e.g., buried in) a lower insulating layer 107 disposed on a lower portion of the substrate 105 as a form of a lower power line VPR. In some embodiments, the lower insulating layer 107 may be referred to herein as a “second insulating pattern.” The lower insulating layer 107 may include an insulating material such as silicon oxide. Accordingly, the power line may be omitted in the first upper metal layer M1. The first lines M1_I for transmitting a signal may be disposed in the first upper metal layer M1.

The first upper metal layer M1 may further include first vias VI1. The first vias VI1 may be respectively provided under the first lines M1_I of the first upper metal layer M1. The active contact AC and the first line M1_I of the first upper metal layer M1 may be electrically connected to each other through the first via VI1. The gate contact GC and the first line M1_I of the first upper metal layer M1 may be electrically connected to each other through the first via VI1.

The first line M1_I and the first via VI1 thereunder of the first upper metal layer M1 may be respectively formed in separate processes. In other words, the first lines M1_I and the first vias VI1 of the first upper metal layer M1 may be respectively formed in a single damascene process. The semiconductor device according to the present embodiment may be formed using a process less than about 20 nanometers (nm).

A second upper metal layer M2 may be provided in the fourth interlayer insulating film 140. The second upper metal layer M2 may include a plurality of second lines M2_I. Each of the second lines M2_I of the second upper metal layer M2 may have a form of a line or bar extending in the second direction D2. In other words, the second lines M2_I may extend parallel to each other in the second direction D2.

The second upper metal layer M2 may further include second vias VI2 respectively provided under the second lines M2_I. The first line M1_I of the first upper metal layer M1 and the second line M2_I of the second upper metal layer M2 may be electrically connected to each other through the second vias VI2. For example, the second line M2_I and the second vias VI2 thereunder of the second upper metal layer M2 may be formed together in a dual-damascene process.

The first line M1_I of the first upper metal layer M1 and the second line M2_I of the second upper metal layer M2 may include the same material or different materials. For example, the first line M1_I of the first upper metal layer M1 and the second line M2_I of the second upper metal layer M2 may include at least one metal material selected among aluminum, copper, tungsten, molybdenum, ruthenium, and cobalt. Although not shown, metal layers (for example, third, fourth, fifth upper metal layers, and the like) stacked on the fourth interlayer insulating film 140 may be additionally disposed. Each of the stacked metal layers may include lines for routing between cells.

A rear surface via BV in (e.g., penetrating) the substrate 105 to vertically extend to the first and second conductive source/drain patterns SDA and SDB may be provided. The rear surface via BV may include a rear surface via contact BVC and a rear surface via line BVL. The rear surface via contact BVC means a portion of the rear surface via BV in direct contact with the first and second conductive source/drain patterns SDA and SDB. The rear surface via contact BVC may be disposed on the rear surface via line BVL. The rear surface via contact BVC may be integrally connected to the rear surface via line BVL. The rear surface via contact BVC may have a shape of protruding from the rear surface via line BVL in the third direction D3. A width of the rear surface via line BVL in the first direction D1 may be greater than a width of the rear surface via contact BVC in the first direction D1. A width of the rear surface via line BVL in the second direction D2 may be greater than a width of the rear surface via contact BVC in the second direction D2. The rear surface via contact BVC may have a cylindrical form. The rear surface via line BVL may have a form of a line or bar (e.g., a rectangle).

A liner may be interposed between each of the rear surface via lines BVL and the substrate 105. The rear surface via BV may include at least one metal selected from the group consisting of tungsten, molybdenum, ruthenium, cobalt, aluminum, copper, and a combination thereof. The liner may include a silicon-based insulating material (for example, SiO, SiN, SiOC or SiOCN). Each of the first and second conductive source/drain patterns SDA and SDB disposed adjacent to each other in (e.g., along) the first direction D1 may be vertically electrically connected to the rear surface via BV. An insulating material of the substrate 105 may be interposed between the adjacent rear surface vias BV, especially the adjacent rear surface via lines BVL to electrically separate each other. In the present specification, the insulating material of the substrate 105 between the adjacent rear surface via lines BVL may be referred to as an insulating pattern.

The lower power lines VPR may be provided under (and/or in/on a lower portion of) the substrate 105. The lower power lines VPR may extend (e.g., extend primarily/longitudinally) parallel to each other in the first direction D1. The lower power lines VPR may vertically overlap the first PMOSFET region PR1, the second PMOSFET region PR2, the first NMOSFET region NR1, and the second NMOSFET region NR2. The lower power lines VPR may include at least one selected from the group consisting of copper, molybdenum, tungsten, ruthenium, and a combination thereof. A bottom surface of each of the lower power lines VPR may be coplanar with a bottom surface of the substrate 105.

A power transmission network layer PDN may be provided on the bottom surface of the substrate 105. The power transmission network layer PDN may include a plurality of lower lines electrically connected to the lower power lines VPR. For example, the power transmission network layer PDN may include a line network for applying a source voltage or drain voltage to the lower power lines VPR. A portion of the rear surface via lines BVL may be in direct contact with the lower power line VPR.

Referring to FIGS. 1, 2A, 3A, and 3B, the power gating block PGB may be provided in the first region R1. Side blocks SB having different functions may be respectively provided on both sides of the power gating block PGB. The power gating block PGB may include at least one of sub-power gating blocks A1, A2, or A3.

As shown in FIG. 3B, each of the sub-power gating blocks A1, A2, and A3 may include three source/drain patterns SD adjacent to each other in (e.g., along) the first direction D1. The sub-power gating blocks disposed adjacent to each other (for example, A2 and A3) may share one source/drain pattern SD. The three source/drain patterns SD may include a first source/drain pattern SD1, a second source/drain pattern SD2, a third source/drain pattern SD3 interposed between the first source/drain pattern SD1 and the second source/drain pattern SD2.

The rear surface vias BV may include a first rear surface via BV1, a second rear surface via BV2, and a third rear surface via BV3. The first rear surface via BV1, the second rear surface via BV2, and the third rear surface via BV3 may respectively penetrate the substrate 105 to be connected (e.g., electrically connected) to the first source/drain pattern SD1, the second source/drain pattern SD2, and the third source/drain pattern SD3.

The lower power lines VPR may include a first lower power line VPR1 and a second lower power line VPR2 spaced apart from each other in the first direction D1. The first lower power line VPR1 and the second lower power line VPR2 may not be in contact with each other. The first rear surface via BV1 may be electrically connected to and in contact with the first lower power line VPR1. The second rear surface via BV2 may be electrically connected to and in contact with the second lower power line VPR2. The third rear surface via BV3 may extend (e.g., extend primarily/longitudinally) in the second direction D2 further (i.e., farther) than the first rear surface via BV1 and the second rear surface via BV2. Specifically, the rear surface via line BVL of the third rear surface via BV3 may extend further than the rear surface via line BVL of the first rear surface via BV1 and the rear surface via line BVL of the second rear surface via BV2. Specifically, a width of the rear surface via line BVL of the third rear surface via BV3 in the second direction D2 may be greater than a width of the rear surface via line BVL of the first rear surface via BV1 in the second direction D2 and a width of the rear surface via line BVL of the second rear surface via BV2 in the second direction D2.

A first voltage may be transmitted to the first lower power line VPR1 so that a first power may be transmitted, through the first rear surface via BV1, the first source/drain pattern SD1, and the channel pattern CH, to the third source/drain pattern SD3. A second voltage may be applied to the second lower power line VPR2 so that a second power may flow, through the second rear surface via BV2, the second source/drain pattern SD2, and the channel pattern CH, to the third source/drain pattern SD3. A third voltage, which is a sum of the first voltage and the second voltage, may be transmitted to the third source/drain pattern SD3 so that a third power may be transmitted through the third rear surface via BV3 to another block connected to the third rear surface via BV3.

Referring to FIGS. 1, 2B, 4 and 6, the switching block SWB, the operation block OPB, and the side block SB may be provided to the second region R2. The side block SB may be placed on one side of the switching block SWB, and the operation block OPB may be placed on the other (e.g., an opposite) side of the switching block SWB. An isolation structure DB may be provided between the switching block SWB and the operation block OPB, and between the switching block SWB and the side block SB. Each of the isolation structures DB may insulate between the switching block SWB and the operation block OPB, and between the switching block SWB and the side block SB.

The switching block SWB may include a switching transistor SWT. The rear surface via BV may further include a fourth rear surface via BV4 and a fifth rear surface via BV5. The fourth rear surface via BV4 and the fifth rear surface via BV5 may be respectively connected to a fourth source/drain pattern SD4 and a fifth source/drain pattern SD5 disposed on opposite (e.g., both) sides of the channel pattern CH of the switching transistor SWT. The lower power lines VPR may further include a third lower power line VPR3 and a fourth lower power line VPR4 spaced apart from each other in the first direction D1. The third lower power line VPR3 and the fourth lower power line VPR4 may not be in contact with each other. The fourth rear surface via BV4 and the third lower power line VPR3 may be electrically connected to and in contact with each other. The fifth rear surface via BV5 and the fourth lower power line VPR4 may be electrically connected to and in contact with each other.

The operation block OPB may include a transistor constituting a logic circuit. An operation transistor may include a sixth source/drain pattern SD6 disposed on one side of the channel pattern CH, and a seventh source/drain pattern SD7 disposed on the other side of the channel pattern CH. The rear surface via BV may be provided on a lower portion of any one of the sixth source/drain pattern SD6 or the seventh source/drain pattern SD7, and the active contact AC may be provided on an upper portion of the other one thereof. For example, the rear surface via BV may be provided on a lower portion of the sixth source/drain pattern SD6, and may be connected to and in contact with the fourth lower power line VPR4. The active contact AC may be provided on and in contact with the upper portion of the seventh source/drain pattern SD7. The third power transmitted from the third rear surface via BV3 of the power gating block PGB may be supplied, through the switching block SWB, to the transistor of the operation block OPB as a source voltage.

Referring to FIGS. 1, 2C, 5, and 6, the operation block OPB may be provided to the third region R3. The operation block OPB may receive power transmitted from the first sub-power gating block A1 and the second sub-power gating block A2 of the power gating block PGB to operate (see FIGS. 1, 3A, and 6).

For example, the rear surface via line BVL of the rear surface via BV connected to the second sub-power gating block A2 may be in contact with the rear surface via contact BVC of the transistor of the operation block OPB. That is, the rear surface via BV connected to the transistor of the second sub-power gating block A2 may share the rear surface via line BVL with the rear surface via BV connected to the transistor of the operation block OPB. The source voltage may be applied to two adjacent operation transistors in the operation block OPB, through the rear surface via contact BVC common thereto.

Referring to FIGS. 1, 2D, and 7, an operation block OPB′ may be provided to the fourth region R4.

The operation block OPB′ may include a pair of adjacent transistors and an isolation structure DB disposed therebetween. The active contact AC may be connected to one source/drain pattern SD of each of the adjacent transistors, and the rear surface via BV may be connected to the other source/drain patterns SD of each thereof. The rear surface vias BV of the adjacent transistors may be in contact with the common lower power line VPR to receive the same power.

Referring to FIGS. 1, 2E, and 8, different operation blocks OPB1 and OPB2 may be provided to the fifth region R5.

The first operation block OPB1 and the second operation block OPB2 may respectively include transistors, and the isolation structure DB may be interposed therebetween. The active contact AC may be connected to one source/drain pattern SD of each of the transistor of the first operation block OPB1, and the transistor of the second operation block OPB2, and the rear surface via BV may be connected to the other source/drain patterns SD of each thereof. The rear surface via BV of the transistor of the first operation block OPB1 and the rear surface via BV of the transistor of the second operation block OPB2 may be respectively connected to different lower power lines VPR. The different lower power lines VPR may respectively supply different powers to the first operation block OPB1 and the second operation block OPB2.

According to the inventive concept, each of adjacent source/drain patterns may be in contact with and connected (e.g., electrically connected) to a rear surface via on a lower portion thereof. In addition, an active contact may not be provided on an upper portion of the source/drain patterns connected to the rear surface via. As a result, transmitting power without passing through a first metal layer and a second metal layer may be advantageous in terms of space utilization in designing lines, and may be desirable in terms of resistance reduction. Connecting the rear surface via to each of the adjacent source/drain patterns may increase a density of the rear surface vias in the same area, and interposing an insulating material therebetween may impede/prevent current from directly flowing therebetween.

In addition, a middle source/drain pattern placed among three consecutive source/drain patterns may be supplied with powers (for example, power 1 and power 2) by the rear surface vias connected to source/drain patterns placed on both sides thereof, and may supply a power, which is a sum (power 1+power 2) greater than the power 1 or the power 2, through the extending rear surface via to another block. In this case, when a power gating block is connected to a switching block, at least the targeted power may be transmitted to an operation block connected to the switching block. According to some embodiments, the middle source/drain pattern placed among the three consecutive source/drain patterns may be supplied with powers (for example, power 1 and −power 2) by the rear surface vias connected to the source/drain patterns placed on both sides thereof, and may supply a power, which is a sum (power 1−power 2) smaller than the power1 or the −power 2, through the extending rear surface via to the other block.

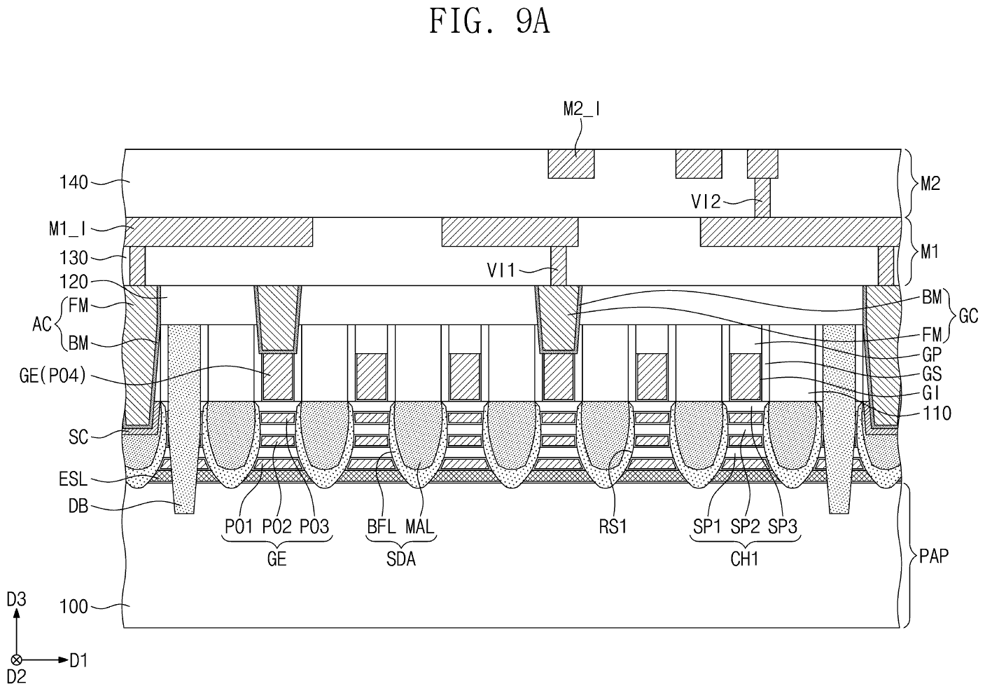

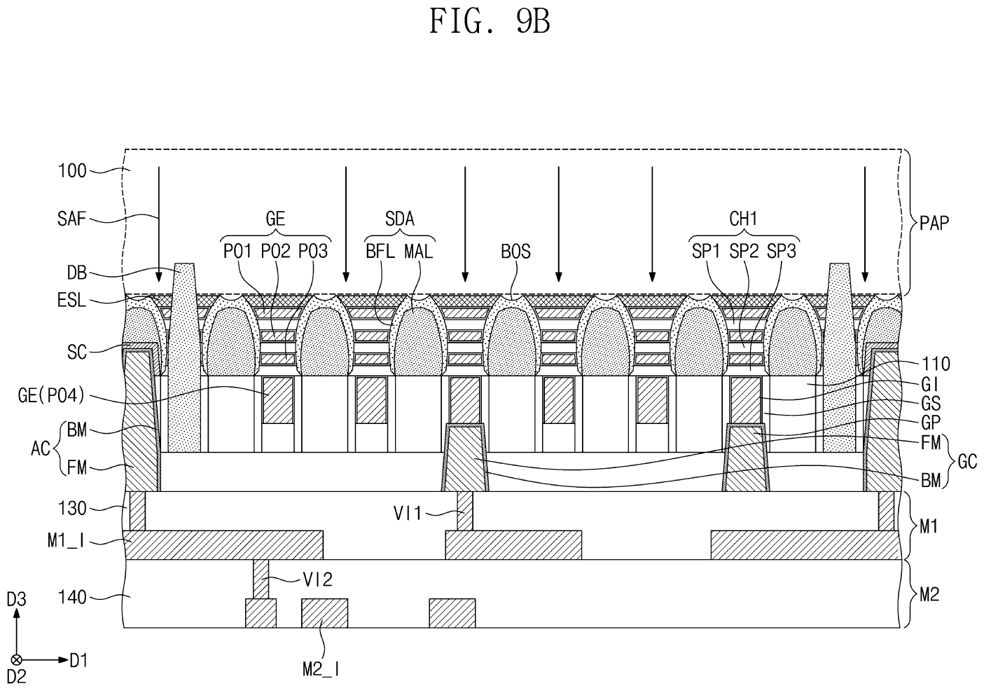

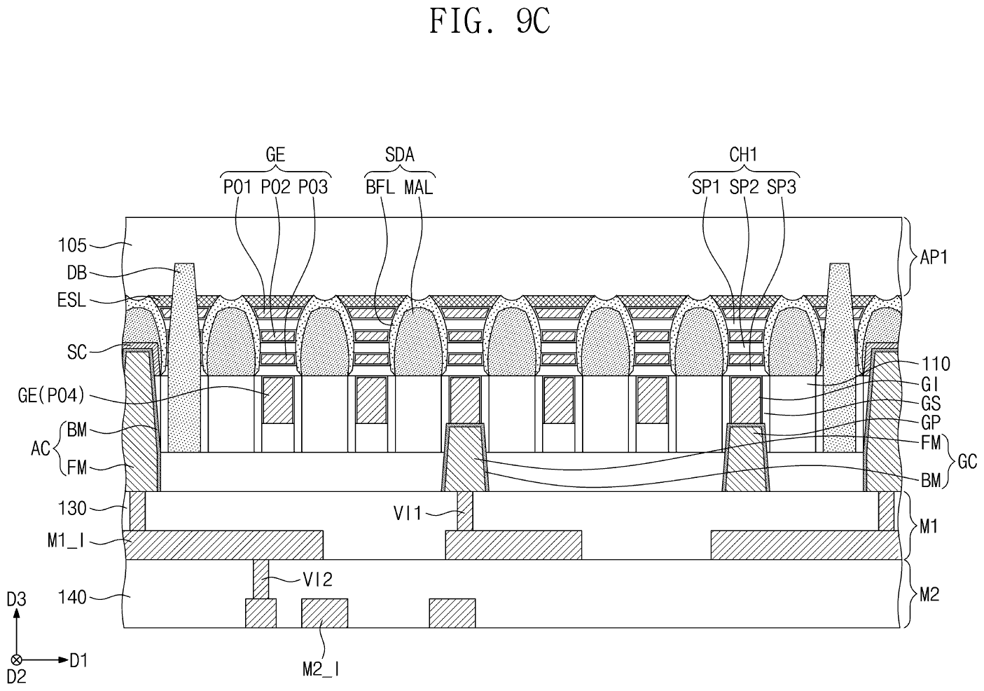

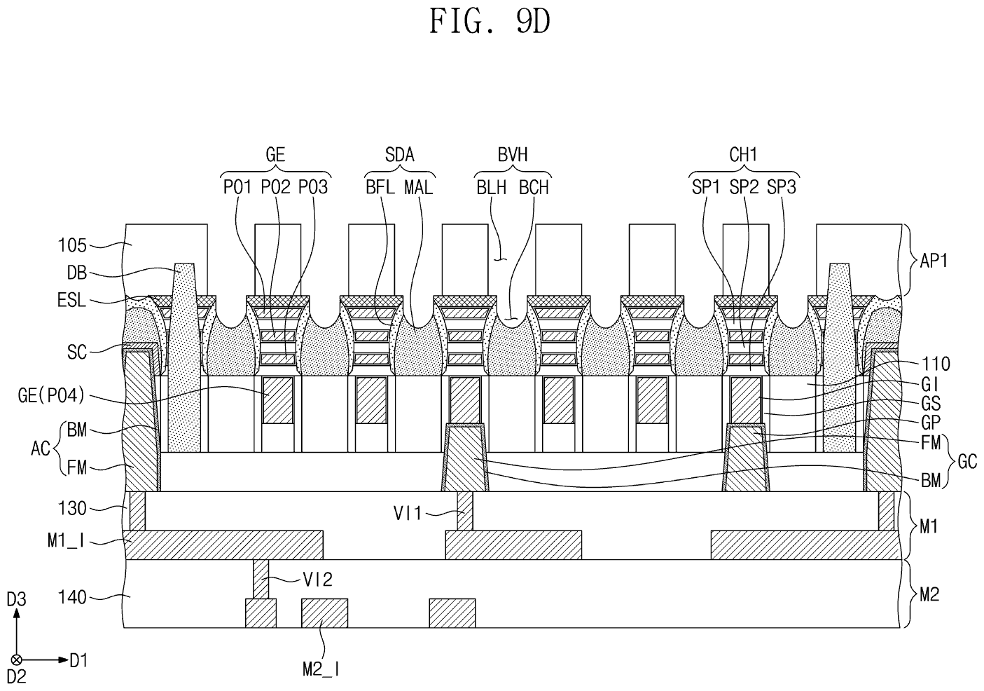

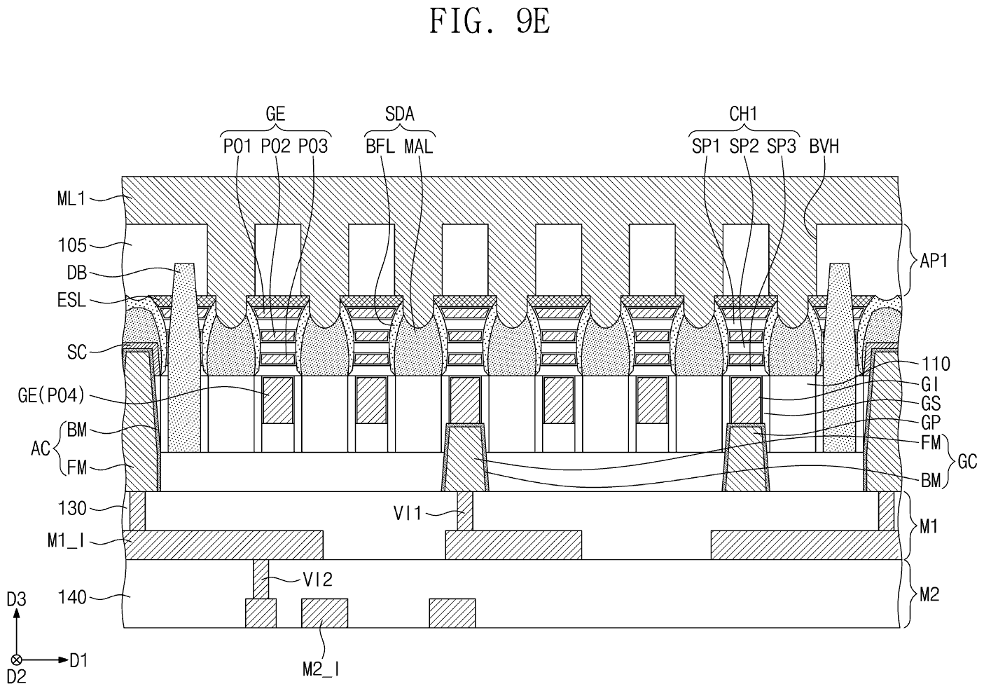

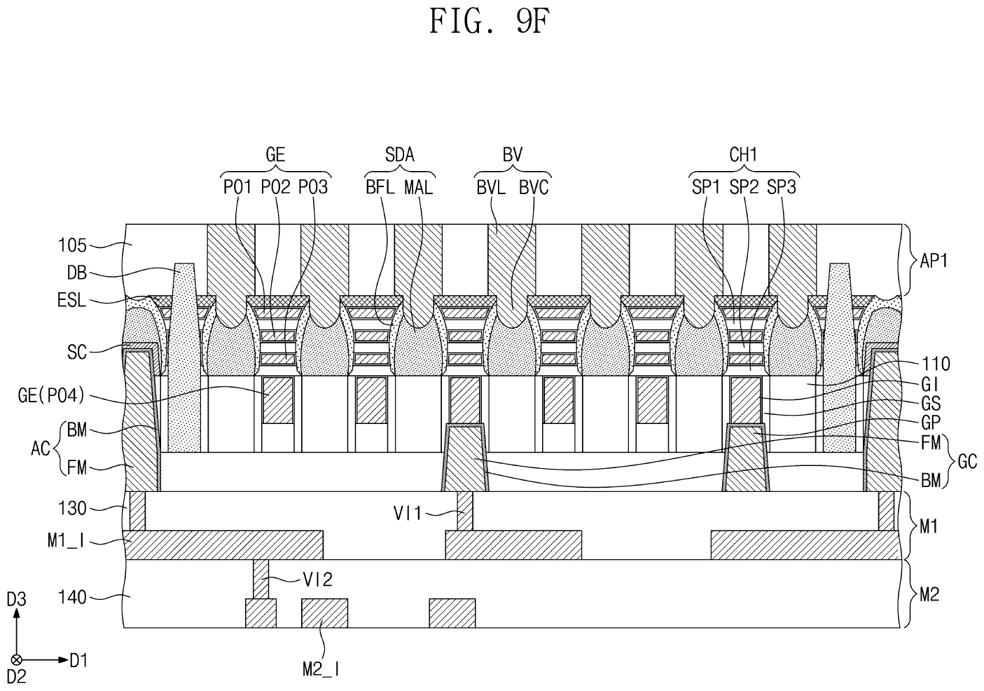

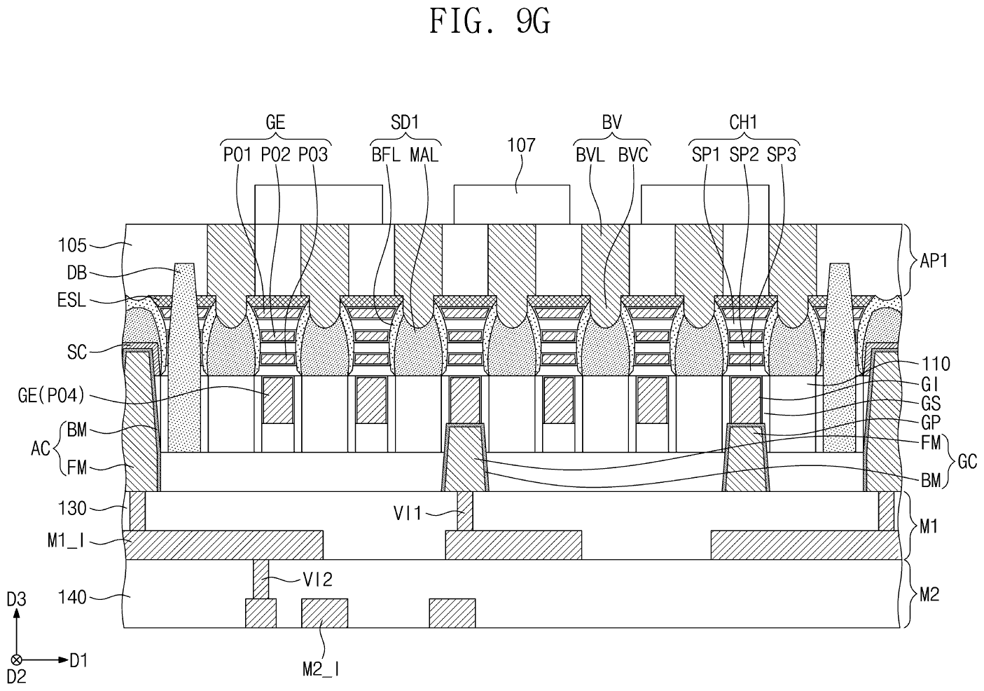

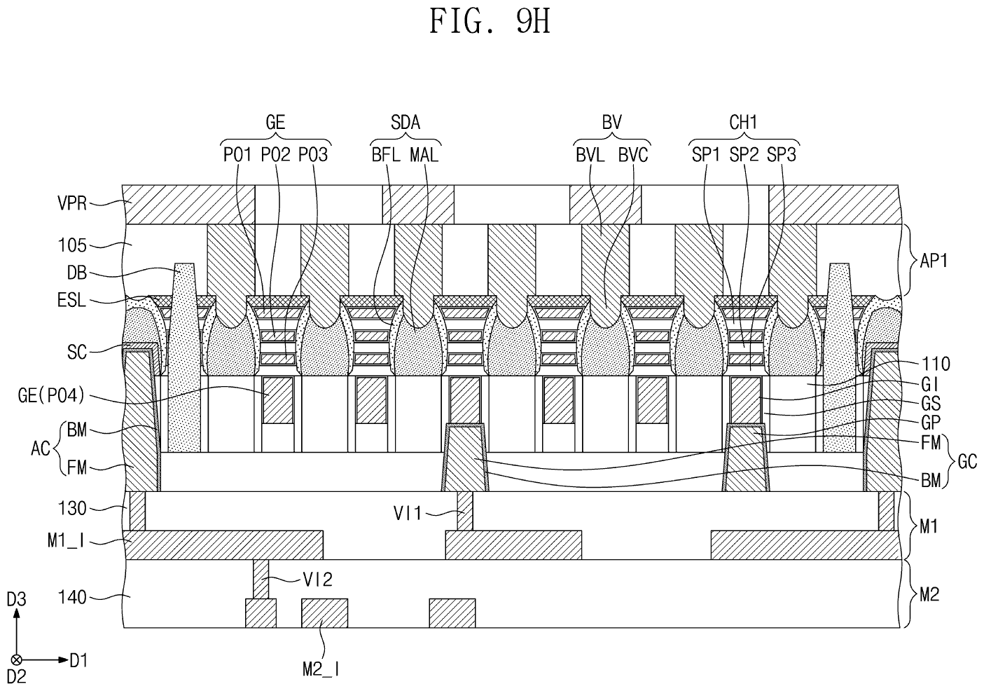

FIGS. 9A to 9H are cross-sectional views for describing a method for manufacturing a semiconductor device according to embodiments of the inventive concept. FIGS. 9A to 9H are cross-sectional views taken along line A-A′ of FIG. 1.

Referring to FIG. 9A, a semiconductor substrate 100 including first and second PMOSFET regions PR1 and PR2 and first and second NMOSFET regions NR1 and NR2 may be provided. For example, the semiconductor substrate 100 may be a silicon wafer. An etch stopping layer ESL may be formed on the semiconductor substrate 100. The etch stopping layer ESL may be formed so as to have etching selectivity with the semiconductor substrate 100, that is, silicon (Si). According to some embodiments, forming the etch stopping layer ESL may be omitted.

Semiconductor layers and sacrificial layers alternately stacked may be formed on the etch stopping layer ESL. For example, the semiconductor layers may include silicon (Si), and the sacrificial layers may include silicon-germanium (SiGe).

Mask patterns may be respectively formed on the first and second PMOSFET regions PR1 and PR2 and the first and second NMOSFET regions NR1 and NR2 of the semiconductor substrate 100. The mask pattern may have a form of a line or bar extending in the first direction D1. A trench TR (see FIG. 1) defining active patterns PAP may be formed by performing a patterning process using the mask patterns as etching masks. The active patterns PAP may be formed on each of the first and second PMOSFET regions PR1 and PR2 and on each of the first and second NMOSFET regions NR1 and NR2. Therebefore, a stacked pattern may be formed by simultaneously patterning the semiconductor layers and the sacrificial layers. An element isolation film that fills the trench may be formed. The stacked patterns may be exposed on the element isolation film.

Sacrificial patterns crossing the stacked patterns may be formed on the semiconductor substrate 100. A pair of gate spacers GS may be formed on both sidewalls of each of the sacrificial patterns. Successively, first recesses RS1 and second recesses RS2 may be formed. First to third semiconductor patterns SP1, SP2, and SP3 sequentially stacked between the adjacent first recesses RS1 may be formed from the semiconductor layers. First to third semiconductor patterns SP1, SP2, and SP3 sequentially stacked between the adjacent second recesses RS2 may be formed from the semiconductor layers. The first to third semiconductor patterns SP1, SP2, and SP3 between the adjacent first recesses RS1 may constitute a first channel pattern CH1. The first to third semiconductor patterns SP1, SP2, and SP3 between the adjacent second recesses RS2 may constitute a second channel pattern CH2.

First conductive source/drain patterns SDA may be respectively formed in the first recesses RS1. A buffer layer BFL may be formed by performing a first selective epitaxial growth (SEG) process, and a main layer MAL may be formed by performing a second SEG process. Second conductive source/drain patterns SDB may be respectively formed in the second recesses RS2. The second conductive source/drain patterns SDB may be formed by performing a selective epitaxial growth (SEG) using an inner sidewall of the second recess RS2 as a seed layer.

A first interlayer insulating film 110 covering the first and second conductive source/drain patterns SDA and SDB may be formed. The first and second channel patterns CH1 and CH2 may be exposed by removing the sacrificial patterns. An empty space between the first to third semiconductor patterns SP1, SP2, and SP3 may be secured by removing the sacrificial films. A gate insulating film GI may be conformally formed on the exposed first to third semiconductor patterns SP1, SP2, and SP3. A gate electrode GE may be formed on the gate insulating film GI. A gate capping pattern GP may be formed on the gate electrode GE.

Cutting holes and isolation holes may be formed by performing an etching process in a space in which the sacrificial pattern is removed. The cutting holes may be formed between the adjacent gate spacers GS. The isolation holes may be formed on opposite (e.g., both) sides of one cell. The isolation holes may penetrate the gate capping pattern GP, the gate electrode GE, and the element isolation film ST, to extend into the semiconductor substrate 100. The isolation holes may extend to an upper portion of the semiconductor substrate 100. A gate cutting pattern CT and an isolation structure DB may be formed by filling each of the cutting holes and the isolation holes with an insulating material. As another example, the gate cutting pattern CT and the isolation structure DB may be simultaneously formed by simultaneously filling the cutting holes and the isolation holes with an insulating material. According to some embodiments, after the cutting holes are filled with the insulating material, the isolation holes may be formed. For example, the gate cutting pattern CT and the isolation structure DB may be formed in different processes.

A second interlayer insulating film 120 may be formed on the first interlayer insulating film 110. An active contact AC penetrating the first interlayer insulating film 110 and the second interlayer insulating film 120 to be electrically connected to at least one of the first and second conductive source/drain patterns SDA and SDB may be formed. A gate contact GC penetrating the second interlayer insulating film 120 and the gate capping pattern GP to be electrically connected to the gate electrode GE may be formed. A third interlayer insulating film 130 may be formed on the active contacts AC and the gate contacts GC. A first upper metal layer M1 may be formed in the third interlayer insulating film 130. A fourth interlayer insulating film 140 may be formed on the third interlayer insulating film 130. A second upper metal layer M2 may be formed in the fourth interlayer insulating film 140.

Referring to FIG. 9B, after a back-end-of-line (BEOL) process is completed, a bottom surface of the semiconductor substrate 100 may be exposed by turning over the semiconductor substrate 100. At least a portion of the exposed semiconductor substrate 100 may be removed.

According to an embodiment of the inventive concept, removing the semiconductor substrate 100 may include reducing a thickness of the semiconductor substrate 100 by performing a process of planarizing the bottom surface of the semiconductor substrate 100, and performing an etching process of selectively removing silicon (Si) on the semiconductor substrate 100. For example, the etching process may be performed until the etch stopping layer ESL is exposed. Lower portions of the first and second conductive source/drain patterns SDA and SDB may be slightly removed by removing the semiconductor substrate 100. Accordingly, a concave bottom BOS may be formed on lower portions of the first and second conductive source/drain patterns SDA and SDB. A rear surface trench may be formed in a region in which the active pattern PAP was present, by removing the semiconductor substrate 100.

Referring to FIG. 9C, a substrate 105 may be formed by filling, with an insulating material, a region in which the semiconductor substrate 100 is removed. The substrate 105 may thus be referred to herein as an “insulating substrate.” The substrate 105 may include a silicon-based insulating layer. A first insulating pattern AP1 and a second insulating pattern AP2 that fill the rear surface trench may be simultaneously formed.

Referring to FIG. 9D, rear surface via holes BVH may be formed by performing a photolithography process and an anisotropic etching process on the substrate 105. The rear surface via holes BVH may include a rear surface contact hole BCH in (e.g., penetrating) at least portions of the first and second conductive source/drain patterns SDA and SDB, and a rear surface line hole BLH in (e.g., penetrating) the substrate 105 connected thereto. The rear surface via holes BVH may expose the first conductive source/drain pattern SDA, and the second conductive source/drain pattern SDB. After patterning, the substrate 105 may remain vertically overlapping the gate electrode GE and the isolation structures DB. A liner may be formed on an inner sidewall of each of the rear surface via holes BVH.

Referring to FIG. 9E, a first lower metal layer ML1 may be formed by filling the rear surface via holes BVH with metal. The first lower metal layer ML1 may fill the rear surface via holes BVH, and may cover an upper surface of the substrate 105.

Referring to FIG. 9F, through the planarization process, the first lower metal layer ML1 may be patterned to form a plurality of rear surface vias BV (for example, a damascene process). The plurality of rear surface vias BV may be separated from each other, and may be electrically insulated by the substrate 105.

Referring to FIG. 9G, a lower insulating layer 107 may be formed and patterned using a photolithography process, or the like. As a result of patterning, the lower insulating layer 107 may expose some (but not all) of the plurality of rear surface vias BV and cover others of the plurality of rear surface vias BV.

Referring to FIG. 9H, a lower power line VPR may be formed. The lower power line VPR may be connected to at least one of the rear surface vias BV. Forming the lower power line VPR may include forming a second lower metal layer, and patterning the second lower metal layer (for example, a damascene process).

Referring back to FIG. 2A, a power transmission network layer PDN may be formed on the lower power line VPR. The power transmission network layer PDN may be formed so as to apply a source voltage or drain voltage to the lower power line VPR.

According to the inventive concept, in a transistor that transmits power, first and second rear surface vias may be respectively connected (e.g., electrically connected), with one channel pattern therebetween, to first and second source/drain patterns connected (e.g., electrically connected) to the channel pattern along a first direction. The first rear surface via may be connected (e.g., electrically connected) to a first rear surface power line vertically overlapping the first source/drain pattern. The second rear surface via may extend in a second direction perpendicular to the first direction to be directly connected to (e.g., in contact with) a lower power line not vertically overlapping the second source/drain pattern, or a third source/drain pattern of another transistor. Transmitting power without passing through an active contact or an upper line disposed on the source/drain pattern may be advantageous in terms of space utilization in designing lines, and may reduce resistance due to power path reduction. As a result, electrical characteristics and reliability of a semiconductor device may be improved.

Although embodiments of the inventive concept have been described, it is understood that the inventive concept should not be limited to these embodiments but various changes and modifications can be made by one ordinary skilled in the art within the scope of the inventive concept as hereinafter claimed.

What is claimed is:

1. A semiconductor device comprising:
a substrate; and
a first block on the substrate,
wherein the first block includes:
a first source/drain pattern, a second source/drain pattern, and a third source/drain pattern between the first source/drain pattern and the second source/drain pattern, the first, second, and third source/drain patterns being spaced apart from each other in a first direction parallel to an upper surface of the substrate;
a first lower power line on a lower portion of the substrate, and a second lower power line spaced apart from the first lower power line in the first direction, the first and second lower power lines extending in the first direction;
a first rear surface via in the substrate, and connecting the first lower power line and the first source/drain pattern;
a second rear surface via in the substrate, and connecting the second lower power line and the second source/drain pattern; and
a third rear surface via in the substrate, and connected to the third source/drain pattern, and
wherein the third rear surface via extends in a second direction parallel to the upper surface of the substrate, and perpendicular to the first direction.

2. The semiconductor device of claim 1, wherein the first, second, and third rear surface vias comprise:
a first rear surface via contact, a second rear surface via contact, and a third rear surface via contact respectively in contact with the first, second, and third source/drain patterns; and
a first rear surface via line, a second rear surface via line, and a third rear surface via line respectively on the first, second, and third rear surface via contacts, and
wherein a width of the third rear surface via line in the second direction is greater than a width of the first rear surface via line in the second direction, and a width of the second rear surface via line in the second direction.

3. The semiconductor device of claim 1, further comprising a third lower power line spaced apart from at least one of the first lower power line or the second lower power line in the second direction,
wherein the third lower power line is connected to the third rear surface via.

4. The semiconductor device of claim 3, wherein the third lower power line extends in the first direction in parallel with the at least one of the first lower power line or the second lower power line.

5. The semiconductor device of claim 3, further comprising a second block connected to the first block,
wherein the second block includes:
a fourth source/drain pattern and a fifth source/drain pattern spaced apart from each other in the first direction;
a fourth lower power line on the lower portion of the substrate, and spaced apart from the third lower power line in the first direction;
a fourth rear surface via in the substrate, and connecting the third lower power line and the fourth source/drain pattern; and
a fifth rear surface via in the substrate, and connecting the fourth lower power line and the fifth source/drain pattern.

6. The semiconductor device of claim 5, further comprising isolation structures spaced apart from each other in the first direction, with the fourth source/drain pattern and the fifth source/drain pattern therebetween.

7. The semiconductor device of claim 5, further comprising a third block connected to the second block,
wherein the third block includes:
a sixth source/drain pattern and a seventh source/drain pattern spaced apart from each other in the first direction;
a sixth rear surface via in the substrate, and connecting the fourth lower power line and a lower side of the sixth source/drain pattern; and
an active contact on an upper side of the seventh source/drain pattern.

8. The semiconductor device of claim 3,
wherein the first lower power line is configured to have a first voltage applied thereto,
wherein the second lower power line is configured to have a second voltage applied thereto, and
wherein the third lower power line is configured to have a sum of the first voltage and the second voltage transmitted thereto.

9. The semiconductor device of claim 1, further comprising a second block connected to the first block,
wherein the third rear surface via includes a first rear surface via contact, a second rear surface via contact, and a rear surface via line on the first rear surface via contact and the second rear surface via contact,
wherein the second block includes a fourth source/drain pattern and a fifth source/drain pattern spaced apart from each other in the first direction,
wherein the first rear surface via contact is in contact with the third source/drain pattern, and
wherein the second rear surface via contact is in contact with any one of the fourth source/drain pattern or the fifth source/drain pattern.

10. The semiconductor device of claim 1, wherein the substrate is an insulating substrate.

11. The semiconductor device of claim 10, wherein the substrate comprises at least one of silicon nitride, silicon oxide, or silicon carbide.

12. The semiconductor device of claim 1, further comprising a power transmission network layer under the substrate,
wherein the power transmission network layer is configured to apply a source voltage or a drain voltage to the first lower power line and the second lower power line.

13. A semiconductor device comprising:
a channel pattern including a plurality of semiconductor patterns stacked spaced apart from each other;
a first source/drain pattern and a second source/drain pattern respectively connected to opposite sides of the channel pattern, and spaced apart from each other in a first direction;
a gate electrode, on the channel pattern, including a plurality of inner electrodes respectively between the plurality of semiconductor patterns;
a first rear surface via connected to the first source/drain pattern;
a second rear surface via connected to the second source/drain pattern;
a lower power line under and connected to at least one of the first rear surface via or the second rear surface via;
an interlayer insulating layer on the first source/drain pattern and the second source/drain pattern, and in contact with upper surfaces of the first and second source/drain patterns; and
a first insulating pattern between the first rear surface via and the second rear surface via.

14. The semiconductor device of claim 13, wherein the first insulating pattern comprises at least one of silicon nitride, silicon oxide, or silicon carbide.

15. The semiconductor device of claim 13, wherein the first insulating pattern is vertically overlapped by the gate electrode.

16. The semiconductor device of claim 13, further comprising:
a first isolation structure on a side surface of the first source/drain pattern; and
a second isolation structure on a side surface of the second source/drain pattern,
wherein the first isolation structure and the second isolation structure are spaced apart from each other, with the first rear surface via and the second rear surface via therebetween.

17. The semiconductor device of claim 13,
wherein the first rear surface via is spaced apart from the lower power line,
wherein the second rear surface via is in contact with the lower power line, and
wherein the first rear surface via extends in a second direction perpendicular to the first direction farther than the second rear surface via.

18. The semiconductor device of claim 13,
wherein the lower power line is one among a plurality of lower power lines,
wherein the plurality of lower power lines each comprise a first lower power line and a second lower power line,
wherein the first rear surface via is connected to the first lower power line,
wherein the second rear surface via is connected to the second lower power line, and
wherein the semiconductor device further comprises a second insulating pattern between the first lower power line and the second lower power line.

19. The semiconductor device of claim 13, further comprising an etch stopping layer between the first insulating pattern and the channel pattern,
wherein the etch stopping layer includes silicon doped with oxygen (O), carbon (C), or a combination thereof.

20. A semiconductor device comprising:
an insulating substrate; and
a first block and a second block on the insulating substrate,
wherein the first block includes:
a first source/drain pattern, a second source/drain pattern, and a third source/drain pattern between the first source/drain pattern and the second source/drain pattern, the first, second, and third source/drain patterns being spaced apart from each other in a first direction parallel to an upper surface of the insulating substrate;
a first lower power line on a lower portion of the insulating substrate, and a second lower power line spaced apart from the first lower power line in the first direction, the first and second lower power lines extending in the first direction;
a first rear surface via in the insulating substrate, and connecting the first lower power line and the first source/drain pattern;
a second rear surface via in the insulating substrate, and connecting the second lower power line and the second source/drain pattern; and
a third rear surface via in the insulating substrate, and connected to the third source/drain pattern,
wherein the second block includes:
a channel pattern including a plurality of semiconductor patterns stacked spaced apart from each other; and
a fourth source/drain pattern and a fifth source/drain pattern respectively connected to opposite sides of the channel pattern, and spaced apart from each other in the first direction, and
wherein the third rear surface via extends in a second direction parallel to an upper surface of the insulating substrate, and perpendicular to the first direction, to connect to any one of the fourth source/drain pattern or the fifth source/drain pattern.
